(19) United States
(12) Patent Application Publication
(10) Pub. No.: US 2025/0189349 A1
(43) Pub. Date: Jun. 12, 2025

(54) HAND DETECTION APPARATUS FOR A STEERING WHEEL DEVICE AND STEERING WHEEL ARRANGEMENT HAVING THE HAND DETECTION APPARATUS

(71) Applicant: ZF AUTOMOTIVE GERMANY GMBH, Alfdorf (DE)

(72) Inventor: Johann SCHMID, Neubeuern (DE)

(21) Appl. No.: 18/844,969

(22) PCT Filed: Feb. 23, 2023
(86) PCT No.: PCT/EP2023/054507

§ 371 Date: Sep. 8, 2024

(30) Foreign Application Priority Data
Mar. 9, 2022 (DE) 10 2022 105 486.1

(51) Int. Cl. G01D 5/24; B62D 1/04

(52) U.S. Cl. CPC G01D 5/24; B62D 1/046

(57) ABSTRACT

In the field of the semi-autonomous or fully autonomous driving, it is important to be able to monitor whether a driver is holding a steering wheel with their hand or whether the driver is leaving the steering wheel unattended. Hands-on detection/HOD systems are now often installed and involve measuring a capacitance which changes when at least one hand is placed on the steering wheel. The invention relates to a hand detection apparatus 1 for a steering wheel device 2 of a vehicle comprising: a sensor layer 7, the sensor layer 7 having at least one conductive sensor portion 9; a signal generator device 15, the signal generator device 15 being designed to generate an excitation signal 22 and being coupled to the sensor layer 7 in order to transfer the excitation signal 22 to the sensor layer 7; a signal recognition device 16 for recognizing a response signal 23, in response to the excitation signal 22, from the sensor layer 7, the signal generator device 16 being coupled to the sensor layer 7 in order to transfer the response signal 23 to the signal recognition device 16; an evaluation device 17, the evaluation device 17 being designed to determine a change in a sensor capacitance 19 caused by at least one hand being placed on and/or removed from the steering wheel device 2 on the basis of the recognized response signal 23 and the signal generator device 15 being designed to generate a rectangular signal as the excitation signal 22.

### TECHNICAL FIELD

The invention relates to a hand detection apparatus comprising the features of the preamble of claim 1. The invention further relates to a steering wheel arrangement having the hand detection apparatus.

### BACKGROUND

In the field of semi-autonomous or fully autonomous driving, it is important to be able to monitor whether a driver is holding a steering wheel with their hand or whether the driving is leaving the steering wheel unattended. Hands-on detection/HOD systems are now often installed and involve measuring a capacitance which changes when at least one hand is placed on the steering wheel.

The document DE 102014223128 A1 which constitutes the closest state of the art discloses a steering wheel comprising a sensor structure for hands-on detection of a heated contact surface, comprising: a contact surface forming at least a part of the outer layer of the steering wheel; a steering wheel skeleton; a sensor portion in which at least one sensor electrode for hands-on detection and at least one heating wire are arranged; and a potential layer interposed between the sensor heating layer and the steering wheel skeleton, wherein a defined potential can be applied to the potential layer.

### SUMMARY

It is an object of the invention to simplify the structure of a hands-on detection. This object is achieved by a hand detection apparatus for a steering wheel device comprising the features of claim 1 and by a steering wheel arrangement comprising the features of claim 14. Preferred embodiments of the invention result from the subclaims and the following description with the figures.

The invention discloses a hand detection apparatus that is suitable and/or designed for a steering wheel device of a vehicle. The vehicle may be a passenger car, a truck, but also a bicycle, tricycle, etc.

The vehicle includes a steering wheel device, wherein the steering wheel device preferably can comprise a round steering wheel. However, it is also possible that the steering wheel device is reduced to two handle areas and/or is designed like a horizontal eight. It is also possible that the steering wheel device is designed as a handle bar having two handle bar ends.

The hand detection apparatus includes a sensor layer, the sensor layer forming at least one conductive sensor portion. The conductive sensor portion can be in the form of a single wire, a grid of wires or the like. In particular, the conductive sensor portion is and/or can be integrated in a grip area of the steering wheel device. For example, the conductive sensor portion has a metallic sensor cable.

The hand detection apparatus includes a signal generator device being designed to generate a particularly periodic excitation signal. The excitation signal thus can be described by the wave shape and a frequency, specifically a generator frequency, and/or a period. The signal generator device is coupled to the sensor layer to transfer the excitation signal to the sensor layer, specifically to the conductive sensor portion. For example, the signal generator device and the sensor layer, specifically the conductive sensor portion, are conductively and/or galvanically connected to each other for coupling.

The hand detection apparatus includes a signal recognition device for recognizing a response signal to the excitation signal from the sensor layer, specifically from the conductive sensor portion. The signal generator device is coupled to the sensor layer, specifically to the conductive sensor portion, to transfer the response signal to the signal recognition device. In particular, the signal generator device is conductively and/or galvanically connected to the sensor layer, specifically to the conductive sensor portion, for coupling.

Furthermore, the hand detection apparatus includes an evaluation device, the evaluation device being designed to determine a change in a sensor capacitance caused by at least one hand being placed on and/or removed from the steering wheel device, particularly in the area of the sensor layer, specifically of the conductive sensor portion, on the basis of the recognized response signal and optionally in addition on the basis of the excitation signal or of parameters of the excitation signal. The evaluation device is designed particularly in terms of programming and/or circuitry to compare the response signal to the excitation signal or the parameters thereof, particularly the phase thereof, so as to determine the change in the sensor capacitance.

Within the scope of the invention, the signal generator device is suggested to be designed as the excitation signal for generating a rectangular signal. The design of the excitation signal as a rectangular signal offers the advantage that the latter can be generated, in terms of programming and/or circuitry, by far more easily as compared to an otherwise normally used sinusoidal signal.

For the rectangular signal it is only necessary to digitally switch between “high” and “low”, but it is not necessary to control a plurality of intermediate values that define the respective rising sinusoidal flanks. In this way, the invention can be realized on a by far simpler hardware, the hardware requiring no sine wave generator or corresponding oscillators. As a result, it is possible to substantially simplify the structure of the hand detection apparatus.

In a preferred development of the invention, at least portions of the signal generator device are designed as a digital data processing device. The digital data processing device includes at least one digital output, the digital output being capable of adopting at least or exactly two states. In the first state, the digital output is preferably switched to ground (“low”), in the second state the digital output is preferably switched to a signal voltage (high), particularly to a supply voltage of the digital data processing device. By changing the states, the frequency of the excitation signal and/or the rectangular signal can be predetermined. This concretization once more underlines the idea of being able to materialize the hand detection apparatus with an as simple hardware as possible.

In a preferred concretization of the invention, the at least one digital output is designed as GPIO. A GPIO (general purpose input/output) is a general digital contact element on an integrated circuit (IC) whose behavior can be freely determined by logical programming irrespective of whether as an input or output contact. Such output is provided as a standard in commercial microcontrollers and produces virtually no hardware costs as compared to an analogous output or a signal generator.

In a preferred circuit-based implementation, the signal generator device includes at least one dividing resistor, the dividing resistor being arranged in series with the at least one digital output, particularly the GPIO. The dividing resistor connected in series can help define in particular an amplitude of the excitation signal.

In a preferred development of the invention, the digital data processing device includes two of the digital outputs. Preferably, each of the two digital outputs is designed as a GPIO and can adopt at least or exactly the described states. The digital outputs adopt the states in a diametrically opposed manner, the two outputs being preferably switched by a toggle. The signal generator device includes two of the dividing resistors, one of the dividing resistors being arranged in series with one of the outputs. The dividing resistors are combined so that a joint excitation signal is formed.

For example, the dividing resistors are connected at one end to the respective digital output and at the other end conductively to each other. The joint excitation signal is formed by combining the dividing resistors. At the same time, a joint dividing resistor is formed by the dividing resistors. Taking the configuration having only one digital output into consideration, the latter can be toggled between the voltage and the ground so that the resulting rectangular signal is equally changed between the ground and the voltage or an adapted voltage. In case that interferences occur, the voltage level is strongly varied particularly in the “high” state. By the use of two digital outputs in the described circuit, the low signal is achieved to have a first voltage level and the high signal is achieved to have a second voltage level, wherein both voltage levels are below the voltage of the digital outputs and/or above ground. Said circuit allows the rectangular signal to be displayed more stably. As most electronic components anyway include two or more of the digital outputs, specifically the GPIOs, the increased safety of the hand detection apparatus does not involve higher costs.

In a preferred embodiment, the signal generator device forms or includes a or the possibly joint dividing resistor. The dividing resistor forms along with the described sensor capacitance an RC voltage divider, the signal recognition device recognizing the response signal in a center tap of the RC voltage divider. At least an input of the signal recognition device is galvanically connected to said center tap of the RC voltage divider.

The evaluation device is particularly preferred to be designed for determining the change in the sensor capacitance via a phase shift between the excitation signal and the response signal. For determining the phase shift, the response signal is scanned and recorded. The excitation signal is basically known so that only the phase position of the excitation signal is required. Consequently, it is not necessary to process two signal curves with each other, but only the response signal has to be processed to obtain the phase shift.

In a preferred implementation of the hand detection apparatus, the evaluation device is designed to determine the phase shift via a time-discrete and value-discrete digital implementation of a Fourier transformation and/or Fourier series. Said calculation method can help determine the phase shift in a reliable and simple manner.

Particularly preferred, the evaluation device is designed to determine the phase shift exclusively for the main frequency, particularly the generator frequency, of the excitation signal. The main frequency of the excitation signal is particularly the frequency of the first signal term, when the excitation signal is broken down into a spectrum. Since only the phase shift between the rectangular signal as excitation signal and the response signal is to be calculated, the calculation of the main frequency is sufficient.

In possible developments of the invention, also higher frequencies can be taken into account to perform e.g. check calculations or the like.

For a possible implementation of the detection of the phase shift, a goertzel algorithm which is known from literature is used. The goertzel algorithm is a numerical implementation of the integrals for calculating the complex spectral components in the Fourier series. As a result, the goertzel algorithm furnishes a phase position of the response signal, wherein the phase shift can be established via the phase position and the known phase position of the excitation signal.

The sensor layer can be designed independently of a heating mat portion of a steering wheel heating. By aiming at reducing the parts in the steering wheel device, the sensor layer, particularly the sensor portion, can also be provided to be a heating mat portion of the steering wheel heating. In this configuration, the heating mat portion and/or the sensor layer adopts a double function, namely, on the one hand, to define the response signal and, on the other hand, to heat the steering wheel device.

It is interesting that it is possible that the signal recognition device acts on the same center tap of the RC voltage divider. Thus, the excitation signal is not passed through the sensor layer but the sensor layer is only coupled.

In a preferred development of the invention, however, the sensor layer is interposed between the signal generator device and the signal recognition device to be serially, particularly serially galvanically, connected. In this configuration, the excitation signal must actually pass through the sensor layer to arrive at the signal recognition device. This configuration offers the advantage that by recognizing the response signal it can be determined at the same time whether there are line interruptions in the sensor layer. Thus, the hand detection apparatus additionally can take over a self-check and/or a safety function, as with the response signal recognized by the signal recognition device it can be easily determined whether it was generated by the excitation signal. For example, only the main frequency and/or generator frequency of the rectangular signal has to be searched, if the latter is below a limit, the transfer is deemed to be faulty.

For a preferred circuit-based implementation, the digital data processing device comprises the signal recognition device and the evaluation device next to the portion of the signal generator device, particularly without the external circuit.

Accordingly, the digital data processing unit is particularly preferred to be in the form of a microcontroller. Those microcontrollers are available in large units as very inexpensive component parts so that the simplification of the hand detection apparatus results in interesting cost savings as compared to hand detection apparatuses that require a sinusoidal wave as excitation signal.

Another subject matter of the invention relates to a steering wheel arrangement comprising a or the steering wheel device as described above and the hand detection apparatus as described above or, resp., according to any one of the preceding claims.

### BRIEF DESCRIPTION OF THE DRAWINGS

Further features, advantages and effects of the invention will result from the following description of preferred embodiments of the invention and of the attached figures, wherein:

FIG. 1 shows a schematic view of a hand detection apparatus in a steering wheel arrangement as an embodiment of the invention;

FIG. 2 in the same view shows an alternative hand detection apparatus in a steering wheel arrangement as another embodiment of the invention;

FIG. 3 shows a schematic diagram of the hand detection apparatus of the preceding figures for illustrating the measuring principle;

FIG. 4 shows a diagram of the hand detection apparatus in FIG. 1 without the components of the steering wheel heating;

FIG. 5 shows a diagram of the hand detection apparatus in FIG. 2 without the components of the steering wheel heating;

FIG. 6 shows a spectrum of the response signal in the hand detection apparatus in the preceding figures.

### DESCRIPTION

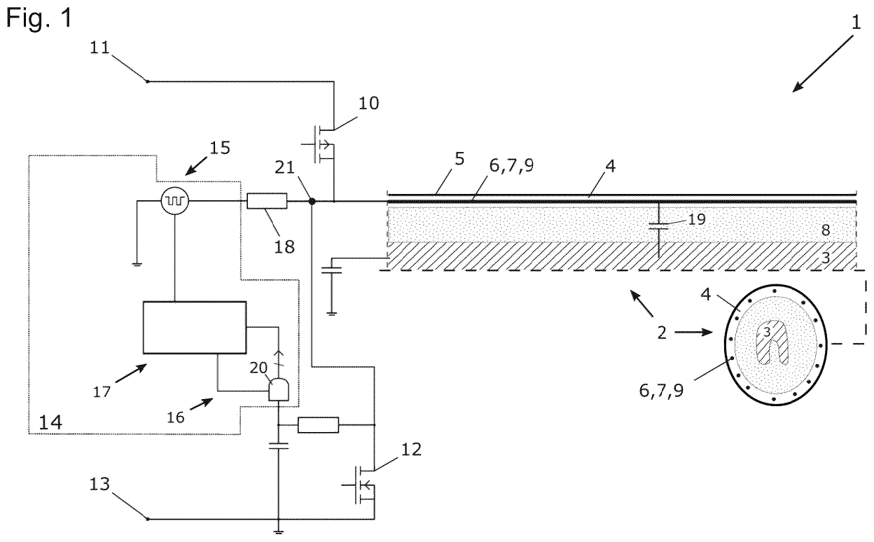

FIG. 1 shows, in a schematic view, a hand detection apparatus 1 for a steering wheel device 2 as an embodiment of the invention. The hand detection apparatus 1 has the function to detect whether at least one hand of a driver is placed on the steering wheel device 2 or whether the steering wheel device 2 is free of contact.

The steering wheel device 2 includes a steering wheel skeleton 3 comprising—in this embodiment-a peripheral steering ring 4 which is schematized additionally with its layers. The steering ring 4 can be formed integrally with the steering wheel skeleton, alternatively the steering ring 4 and the steering wheel skeleton 3 are two different component parts which are interconnected to be electrically conducting, however. On the steering ring 4, an outer spacing layer 5 such as a leather wrapping or plastic wrapping is arranged. Adjacent thereto, there is provided a heating mat layer 6 which at the same time forms a sensor layer 7. The layer structure abuts on the steering ring 4 via a foam layer 8.

The shown cross-section reveals that the heating mat layer 6 and/or the sensor layer 7 is/are formed by a conductive heat wire coiled around the steering wheel ring 4. Thus, the sensor layer 7 forms at least one conductive sensor portion 9. On the input side, the heating mat layer 6 is connected to a supply voltage 11 of the vehicle via a first circuit element 10. On the output side, the heating mat layer 6 is connected to a ground 13 of the vehicle via a second circuit element 12.

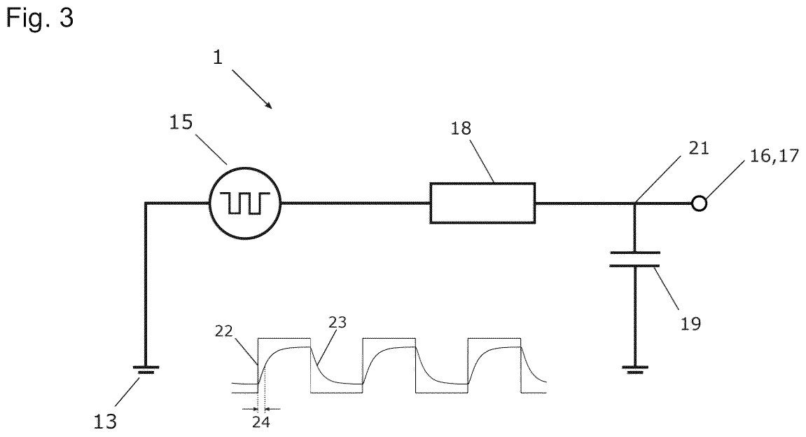

The hand detection apparatus 1 includes a digital data processing unit 14, the digital data processing unit 14 at least partly forming a signal generator device 15 and forming a signal recognition device 16 and an evaluation device 17. The signal generator device 15 is designed program-based and/or circuit-based so as to form a periodic excitation signal 22 (FIG. 3), the periodic excitation signal 22 being coupled into the sensor layer 7, particularly the conductive sensor portion 9, via a dividing resistor 18.

Considering the sensor layer 7, particularly the conductive sensor portion 9, the latter can be displayed as a sensor capacitance 19 in accordance with an equivalent circuit diagram, the sensor capacitance 19 being defined vis-à-vis the steering wheel skeleton 3 and, thus, a ground of the vehicle such as the ground 13. The excitation signal 22 passes through or connects to the sensor layer 7 and is recognized by an analog-digital converter 20 as the response signal 23 (FIG. 3). The analog-digital converter 20 is provided by the digital data processing unit 14 and, for example, is in the form of a 12-bit ADC. In the evaluation device 17, the response signal 23 is evaluated and, on the basis of the evaluation, a hand being placed on and/or removed from the steering wheel device 2 is detected.

The illustrated embodiment is a single-layer steering wheel device 2, wherein the heating mat layer 6 and the sensor layer 7 are formed by a uniform conductive layer (“one layer including heating”). In other embodiments, the heating mat layer 6 and the sensor layer 7 can also be galvanically separated from each other. It is preferred for the configuration shown in FIG. 1 that the supply of the heating mat layer 6 with the heating current alternates with the recognition of the response signal 23 by the signal recognition device 16, specifically in a time multiplexing, so that the currents do not mutually interfere.

The detection of at least one hand being placed on and/or removed from the steering wheel device 2 is determined by evaluating the phase position of the response signal 23 relative to the phase position of the excitation signal 22, viz. depending on a phase shift 24 (FIG. 3). It is the basic idea that an RC voltage divider effectuating the phase shift 24 between the excitation signal 22 and the response signal 23 depending on the value of the sensor capacity 19 is formed by the dividing resistor 18 and the sensor capacitance 19.

In the embodiment of FIG. 1, the input to the signal recognition device 16 is connected, optionally via a resistor, directly to a center tap 21 of the RC voltage divider comprising the dividing resistor 18 and the sensor capacitance 19. Consequently, the coupling between the signal generator device 15 and the signal recognition device 16 with the sensor layer 7, particularly the sensor portion 9, is carried out only at one end of the sensor portion 9, the other end being open relative to the detection of the capacitance. This embodiment allows a particularly simple integration of the hand detection apparatus 1.

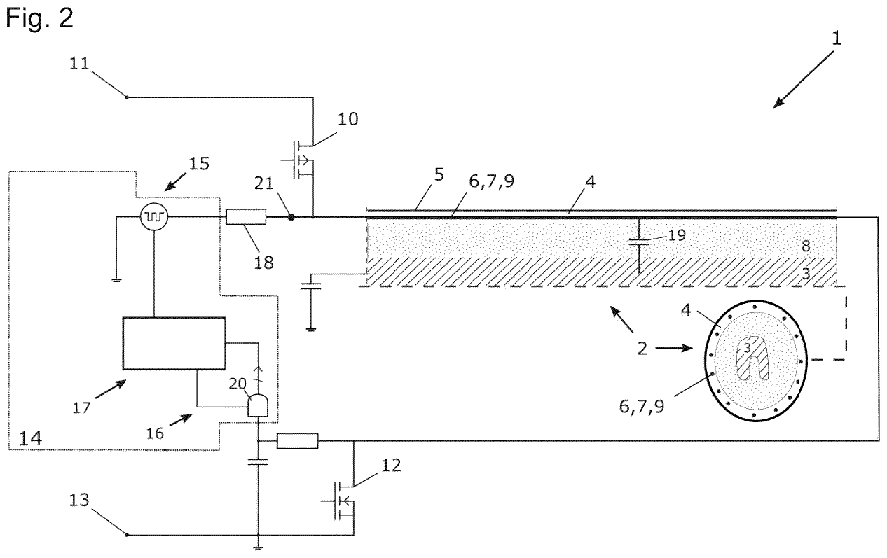

FIG. 2 illustrates an alternative embodiment of the hand detection apparatus 1 which is substantially different by the fact that between the center tap 21 and the signal recognition device 16 the sensor layer 7, particularly the sensor portion 9, is serially connected. Although the signal recognition device 16 is thus equally galvanically connected to the center tap 21, in extended embodiments a safety check as to whether the sensor layer 7, particularly the sensor portion 9, is undamaged, for example, can be performed by serially interconnecting the sensor layer 7 by checking whether the response signal 23 passes from the signal generator device 15 to the signal recognition device 16.

In FIG. 3, the general measuring principle of the hand detection apparatus 1 is exemplified. There are illustrated the signal generator device 15 and the dividing resistor 18 as well as the sensor capacitance 19 and the signal recognition device 16. The dividing resistor 18 and the sensor capacitance 19 form the RC voltage divider. The signal recognition device 16 is connected via the center tap 21. With respect to the phase position, the excitation signal 22 and the response signal are shifted by the phase shift 24, the phase shift 24 being dependent on the sensor capacitance 19. Thus, the sensor capacitance 19 and, resp., a change in the sensor capacitance 19 can be concluded from the phase shift 24 so that in this way a hand being placed on and/or removed from the steering wheel device 2 can be detected. Each of the periodic excitation signal 22 in the form of a rectangular signal and the periodic response signal 23 is designed with an identical fundamental frequency.

The method of detection can be realized as follows:

The measurement of the sensor capacitance 19 of the sensor layer 7 in the steering wheel device is to be realized by using a periodically excited complex voltage divider which is designed as an RC voltage divider. The response signal 23 at the center tap 21 is scanned and processed for determining the capacitance. Accordingly, preferably only a commercial automotive μC (NXP S32K1/3, Infineon Aurix, . . . ) and related passive components as well as ESD protection are to be used.

Measurement of C_sensor as sensor capacitance 19 via the phase shift 24 from the response signal 23 to the excitation signal 22: By sampling the response signal 23 and the dividing resistor 18 as R_div, the phase shift 24 can be established as tanφ between the excitation signal 22 and the response signal:

$$tan φ = \frac{{X}_{C s e n s o r}}{{R}_{d i v}} = \frac{\frac{1}{ω {C}_{s e n s o r}}}{{R}_{d i v}} = \frac{1}{ω {C}_{s e n s o r} {R}_{d i v}}$$

Therefrom the sensor capacitance 19 can be determined as C_sensor:

$${C}_{s e n s o r} = \frac{1}{ω {R}_{div} tan φ}$$

Determination of the phase from a sampling sequence:

In order to establish the phase φ of the sought frequency component of the response signal 23, multiple sampling is required. The latter should provide at least 10 sampling values per period of the excitation signal 22 (at least five points per half-wave already provide good fit). The sampling interval should either be an integer multiple of the period of the excitation signal 22, then the frequency of the excitation signal 22 is exactly contained in the spectrum, or should amount to a multiple of the period so as to obtain a satisfactory resolution within the frequency range.

The longer the sampling interval is selected, the lower the noise of the result on the one side, but also the longer the computing effort for establishing the phase (increases by the square).

When the sampling of the N sampling values is completed, the complex spectrum of the sequence N is established which contains the amplitude and the phase of the frequency of the response signal 23.

Since only the phase and the amplitude of the frequency of the response signal 23 is of interest (known for the excitation signal), the goertzel algorithm which is the numerical implementation of the integrals to calculate the complex spectral components in the Fourier series is suitable for establishing the phase and the amplitude.

Integral for establishing the in-phase and quadrature components of the frequency k:

$${a}_{k} = \frac{1}{T} {\int }_{- \frac{T}{2}}^{\frac{T}{2}} f ( t ) cos ( kt ) dt \\ {b}_{k} = \frac{1}{T} {\int }_{- \frac{T}{2}}^{\frac{T}{2}} f ( t ) sin ( kt ) dt$$

However, these values are only required for the frequency (main frequency/generator frequency) of the response signal 23. The goertzel algorithm allows to calculate for one single frequency:

Algorithm for implementing the integrals in microcontroller or logic (goertzel algorithm):

“function [a,b] = goertzel(A,k,N) % array with min N elements, k frequency component to be
calculated from A , N

| | | | |
|---|---|---|---|
| w = 2*pi*k/N; | cw = cos(w); | c = 2*cw; | sw = sin(w); |

z1=0; z2=0; % init
for n = 1 : N

| | | |
|---|---|---|
| z0 = A(N−n+1) + c*z1 − z2; | z2 = z1; | z1 = z0; |

end

| | | |
|---|---|---|
| a = cw*z1 − z2; | b = sw*z1; | %a in-phase component for frequency |

end”

The phase angle or the phase position is then calculated as b/a with the frequency of the response signal 23. The sought phase shift 24 can be derived from the known phase position of the excitation signal and the phase angle/phase position of the response signal 23. For calculating the phase and the amplitude, in the goertzel algorithm 2N+2 additions (or subtractions, depending on the phase position) and 2N multiplications are necessary per frequency component of the spectrum. The block size N can be freely selected and need not correspond to a power of two as for the FFT algorithm.

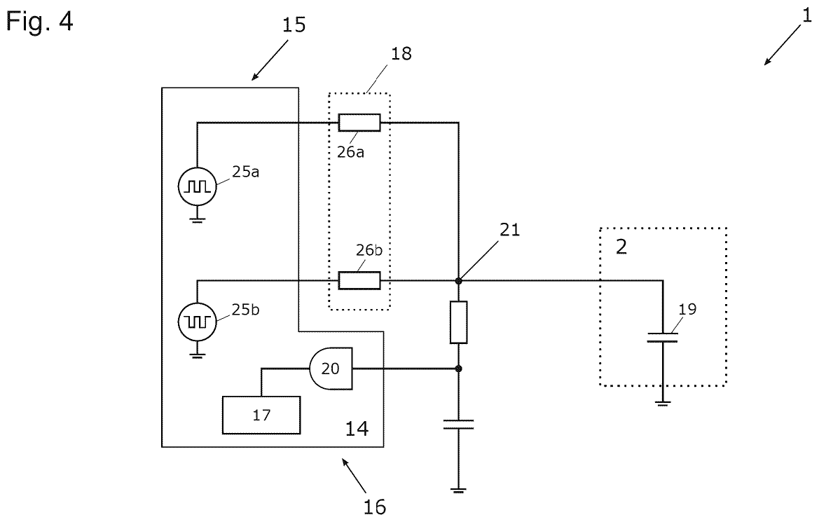

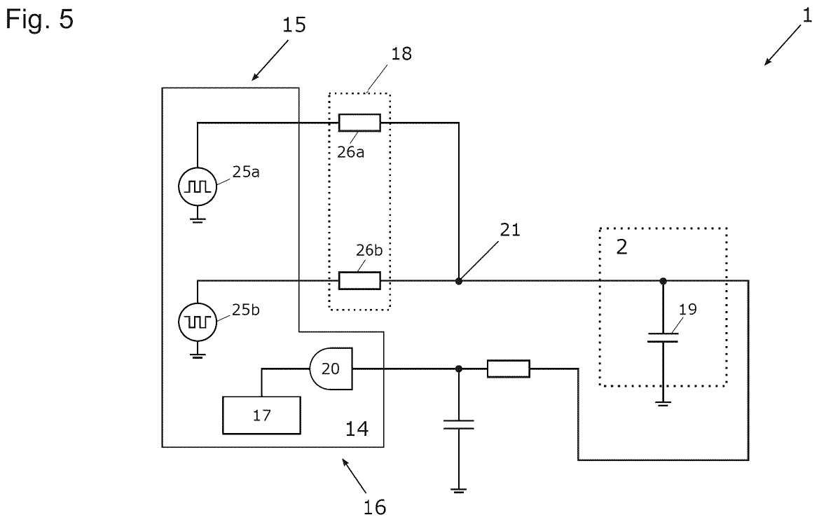

Since a sine-wave generator is expensive, a generator having a rectangular signal shape is used which is part of the diagram in FIGS. 4 and 5 corresponding to the structure in FIG. 1 or 2, wherein identical components are provided with the same reference signs.

The hand detection apparatus 1, particularly the digital data processing unit 14, includes two digital outputs 25 a, b, the digital outputs 25 a, b being designed as GPIO which can assume a first state with ground being applied to the output 25 a, b, and a second state with a voltage signal, particularly the supply voltage of the digital data processing unit 14, being applied to the output 25 a, b. A dividing resistor 26 a, b is serially connected to each of the digital outputs 25 a, b, the dividing resistors 26 a, b jointly resulting in the dividing resistor 18.

The rectangular signal as excitation signal 22 is realized by means of the two digital outputs 25 a, b, viz. the GPIO outputs. A signal amplitude A_gen can be set by the two dividing resistors 26 a, b as R: drv_up and R_drv_down. The mean value of the rectangular voltage is half the operating voltage V_dd.

$${A}_{g e n} = \frac{{V}_{d d}}{2} \frac{{R}_{drv up} - {R}_{drv down}}{{R}_{drv up} + {R}_{drv down}} \\ \overline{{V}_{g e n}} = \frac{{V}_{d d}}{2}$$

The effective resistance R_div of the dividing resistor 18 of the complex voltage divider results from the two GPIOs as voltage sources V_dd and the dividing resistors 26 a, b and R_drv_up, R_drv_down, respectively.

When applying the Helmholtz equation for linear voltage sources, the following results for the joint dividing resistor:

$${R}_{d i v} = \frac{{R}_{drv up} * {R}_{drv down}}{{R}_{drv up} + {R}_{drv down}}$$

The rectangular signal as excitation signal 22 of the signal generator device 15 contains the following spectrum:

$${V}_{g e n} = \overline{{V}_{g e n}} + \frac{4 {A}_{g e n}}{π} [ sin ( 2 π {f}_{g e n} ) + \frac{1}{3} sin ( 6 π {f}_{g e n} ) + \frac{1}{5} sin ( 10 π {f}_{g e n} ) + … ]$$

The rectangular signal as excitation signal 22 is now mapped by means of the linear voltage divider (RC voltage divider) which has the following transfer function:

$${V}_{s e n s o r ( {C}_{s e nsor} )} = {V}_{g e n} \frac{1}{1 + j {ωC}_{s e n s o r} {R}_{d i v}}$$

If the excitation signal 22 is inserted in the transfer function of the voltage divider, the following results for the voltage at the sensor, viz. for the response signal 23:

$${V}_{s e n s o r ( {C}_{s e nsor} )} = \overline{{V}_{g e n}} + \frac{4 {A}_{g e n}}{π} [ \text{} \frac{sin ( 2 π {f}_{g e n} )}{1 + j 2 π {C}_{s e n s o r} {R}_{d i v}} + \frac{sin ( 6 π {f}_{g e n} )}{3 + j 6 π {C}_{s e n s o r} {R}_{d i v}} + \frac{sin ( 10 π {f}_{g e n} )}{5 + j 10 π {C}_{s e n s o r} {R}_{d i v}} + … ]$$

From this representation, the spectrum of the sensor signal as response signal 23 can be directly read and the following conclusions can be drawn:

Each frequency component of the generator signal/excitation signal 22 is mapped onto the components of identical frequency in the sensor signal/response signal 23. A mapping onto components of other frequencies or new frequencies in the sensor signal does not exist (linear transfer function).

In the sensor signal/response signal 23, a sinusoidal signal is contained having exactly the generator frequency f_gen of the rectangular signal as excitation signal 22 and the complex amplitude

$$\frac{4 {A}_{g e n}}{π + j 2 {π}^{2} {C}_{s e n s o r} {R}_{d i v}}$$

and the phase or amplitude can be used to determine C as sensor capacity 19 with a known R as dividing resistor 18.

Accordingly, sinusoidal oscillations having the threefold, fivefold . . . frequency of the fundamental oscillation (generator frequency/main frequency/f_gen) are contained having characteristic phases and amplitudes.

By checking said characteristic amplitude profiles, the calculations of C can be verified against interferences from outside in said frequencies (EE, EMV).

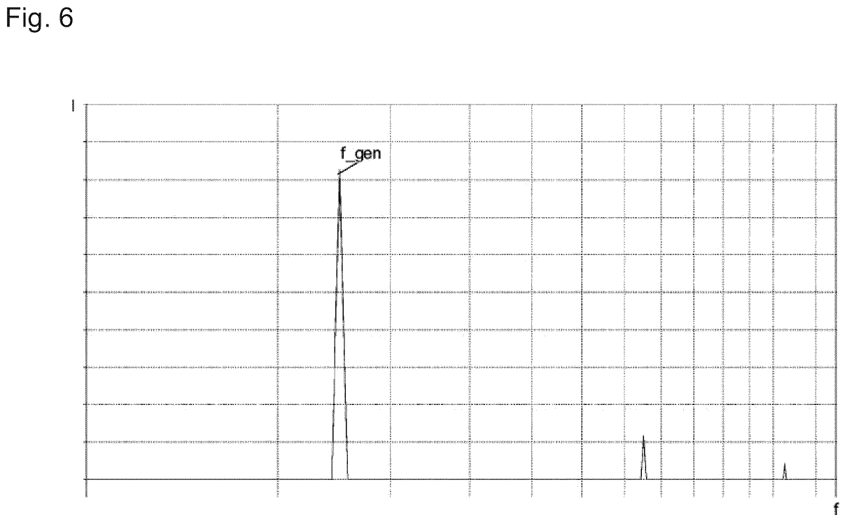

FIG. 6 illustrates the spectrum of the response signal 23, where it can be seen that the main peak with the generator frequency f_gen is arranged isolated from the further frequencies with the threefold, fivefold . . . frequency of the fundamental oscillation (generator frequency/main frequency/f_gen) in the spectrum. Hence, the proof has been furnished that the sensor capacitance 19 and, resp., the change thereof can be determined via evaluation of the frequency of the rectangular voltage as generator frequency f_gen.

By using the digital outputs 25 a, b, conventional microcontrollers can be used for the digital data processing unit 14. An exemplary configuration of the embodiments in the FIGS. 4 and 5 provide the following values:
Dividing resistor 26a: 34.8 k
Dividing resistor 26b: 20 k
Series resistor ahead of the analog-digital converter 20: 20 k

Rating for an approach with μC:

| | |
|---|---|
| sampling frequency: | 500 kS/s-1 MS/s |
| generator frequency: | 25 kHz-100 kHz |
| generator signal shape: | square wave |
| sampling block signal processing | about 500 samples/1 msec |
| resolution ADC | 12 bit |

### Reference Signs

1 hand detection apparatus
2 steering wheel device
3 steering wheel skeleton
4 steering ring
5 outer spacing layer
6 heating mat layer
7 sensor layer
8 foam layer
9 sensor portion
10 first circuit element
11 supply voltage
12 second circuit element
13 ground
14 digital data processing device
15 signal generator device
16 signal recognition device
17 evaluation device
18 dividing resistor
19 sensor capacity
20 analog-digital converter
21 center tap
22 excitation signal
23 response signal
24 phase shift
25 a,b digital outputs
26 a,b dividing resistor

1. A hand detection apparatus for a steering wheel device of a vehicle
comprising a sensor layer, the sensor layer having at least one conductive sensor portion,
comprising a signal generator device, the signal generator device being designed to generate an excitation signal and the signal generator device being coupled to the sensor layer to transfer the excitation signal to the sensor layer,
comprising a signal recognition device for recognizing a response signal in response to the excitation signal from the sensor layer, the signal generator device being coupled to the sensor layer to transfer the response signal to the signal recognition device,
comprising an evaluation device, the evaluation device being designed to determine a change in the sensor capacitance by at least one hand being placed on and/or removed from the steering wheel device on the basis of the recognized response signal,
wherein the signal generator device being designed to generate a rectangular signal as the excitation signal,
wherein at least portions of the signal generator device are designed as a digital data processing device, the digital processing device having at least one digital output, wherein a ground or a voltage is applied to the digital output as states, wherein the frequency of the excitation signal can be preset by the change of the states,
wherein the digital data processing device includes two of the digital outputs, the digital outputs assuming the states diametrically opposed to each other and the signal generator device having two of the dividing resistors, one dividing resistor being arranged in series with each digital output, wherein the dividing resistors are combined so that a joint excitation signal is formed, and wherein the dividing resistors form a joint dividing resistor.

2. (canceled)

3. The hand detection apparatus according to claim 1, wherein the at least one digital output is designed as a GPIO.

4. The hand detection apparatus according to claim 1, wherein the signal generator device has at least one dividing resistor, the dividing resistor is arranged in series with the at least one digital output.

5. (canceled)

6. The hand detection apparatus according to claim 1, wherein the signal generator device has a or the dividing resistor, the dividing resistor forming an RC voltage divider with the sensor capacitance and the signal recognition device recognizing the response signal in a center tap of the RC voltage divider.

7. The hand detection apparatus according to claim 1, wherein the evaluation device is designed to detect the change in the sensor capacitance via a phase shift between the excitation signal and the response signal.

8. The hand detection apparatus according to claim 5, wherein the evaluation device is designed to define the phase shift via time-discrete and value-discrete digital implementation of a Fourier transformation and/or a Fourier series.

9. The hand detection apparatus according to claim 1, wherein the evaluation device is designed to determine the phase shift by determining the phase position of the response signal via a goertzel algorithm.

10. The hand detection apparatus according to claim 1, wherein the sensor layer is designed as a heating mat layer of a steering wheel heater.

11. The hand detection apparatus according to the preceding claim 1, wherein the sensor layer is arranged serially between the signal generator device and the signal recognition device.

12. The hand detection apparatus according to the preceding claim 1, wherein the digital data processing device comprises the signal recognition device and the evaluation device.

13. The hand detection apparatus according to any one of the preceding claim 1, wherein the digital data processing device is designed as a microcontroller.

14. A steering wheel arrangement comprising a steering wheel device and the hand detection apparatus according to any one of the preceding claim 1.
